(19) United States
(12) Patent Application Publication
(10) Pub. No.: US 2022/0408545 A1
(43) Pub. Date: Dec. 22, 2022

(54) HEAT TRANSFER MEMBER-EQUIPPED SUBSTRATE AND METHOD FOR MANUFACTURING HEAT TRANSFER MEMBER-EQUIPPED SUBSTATE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Akira HARAGUCHI, Yokkaichi-shi, Mie (JP)

(21) Appl. No.: 17/755,391

(22) PCT Filed: Sep. 2, 2020
(86) PCT No.: PCT/JP2020/033256

§ 371 Date: Apr. 28, 2022

(30) Foreign Application Priority Data
Oct. 28, 2019 (JP) 2019-195337

(51) Int. Cl. H05K 1/02; H05K 3/34

(52) U.S. Cl. CPC H05K 1/0204; H05K 3/3463; H05K 1/181

(57) ABSTRACT

A heat transfer member-equipped substrate includes a heat transfer member installed in a through hole of a substrate; a heat generating component; and a solder portion soldering the heat generating component to the heat transfer member, a nickel base plating formed on the heat transfer member, and the solder portion bonded to the nickel base plating where a gold plating that suppresses oxidization of the nickel base plating is blended into the solder portion. The heat transfer member includes a first and a second heat transfer portion bonded to each other, the first heat transfer portion made of a first metal, the second heat transfer portion made of a second metal formed on at least a portion of a surface of the second heat transfer portion, and the second heat transfer portion being a plate shape that protrudes from a circumference of the first heat transfer portion.

### CROSS-REFERENCE TO RELATED APPLICATIONS

This application is the U.S. national stage of PCT/JP2020/033256 filed on Sep. 2, 2020, which claims priority of Japanese Patent Application No. JP 2019-195337 filed on Oct. 28, 2019, the contents of which are incorporated herein.

### TECHNICAL FIELD

The present disclosure relates to a heat transfer member-equipped substrate and a method for manufacturing a heat transfer member-equipped substrate.

### BACKGROUND

JP 2009-170493A discloses that a heat transfer member is press-fitted into a heat transfer member fitting hole in a wiring board, that the heat transfer member is formed of a material with favorable heat conductivity such as a copper plate, and that a heat generating component is soldered to the heat transfer member.

There is demand for improvements in the thermal performance of a heat generating component in a heat transfer member-equipped substrate.

Thus, an object of the present disclosure is to improve the thermal performance of a heat generating component.

### SUMMARY

A heat transfer member-equipped substrate of the present disclosure, including: a substrate provided with a through hole; a heat transfer member installed in the through hole; a heat generating component mounted on one main surface side of the substrate; and a solder portion where the heat generating component is soldered to one end surface of the heat transfer member, wherein a nickel base plating layer is formed on at least the one end surface of the heat transfer member, and the solder portion is bonded to the nickel base plating layer in a state where a gold plating layer that suppresses oxidization of the nickel base plating layer is blended into the solder portion.

### Advantageous Effects

With the present disclosure, the thermal performance of a heat generating component is improved.

### BRIEF DESCRIPTION OF DRAWINGS

FIG. 1 is a perspective view showing a heat transfer member-equipped substrate according to an embodiment.

FIG. 2 is a cross-sectional view taken along line II-II in FIG. 1.

FIG. 3 is a perspective view showing a heat transfer member.

FIG. 4 is an exploded perspective view showing the heat transfer member.

FIG. 5 is a perspective view of a substrate.

FIG. 6 is a diagram showing a step of inserting the heat transfer members into the substrate.

FIG. 7 is a diagram showing a step of inserting the heat transfer members into the substrate.

FIG. 8 is a diagram showing a step of soldering heat generating components to the heat transfer member.

FIG. 9 is a diagram showing the substrate on which the heat generating components are mounted.

FIG. 10 is a cross-sectional view showing the step of soldering the heat generating component to the heat transfer member.

FIG. 11 is a diagram showing a step of mounting other components to the substrate.

FIG. 12 is a plane view showing the substrate on which components are mounted.

FIG. 13 is a bottom view showing the substrate on which components are mounted.

FIG. 14 is a diagram showing a step of attaching a heat dissipating member to the substrate.

FIG. 15 is a diagram showing a step of attaching the heat dissipating member to the substrate.

FIG. 16 is a diagram showing voids in a working example.

FIG. 17 is a diagram showing voids in an example.

### DETAILED DESCRIPTION OF PREFERRED EMBODIMENTS

First, embodiments of the present disclosure will be listed and described below.

A heat transfer member-equipped substrate according to the present disclosure is as follows.

A heat transfer member-equipped substrate including: a substrate provided with a through hole; a heat transfer member installed in the through hole; a heat generating component mounted on one main surface side of the substrate; and a solder portion where the heat generating component is soldered to one end surface of the heat transfer member, wherein a nickel base plating layer is formed on at least the one end surface of the heat transfer member, the solder portion is bonded to the nickel base plating layer in a state where a gold plating layer that suppresses oxidization of the nickel base plating layer is blended into the solder portion, the heat transfer member includes a first heat transfer portion provided with the one end surface, and a second heat transfer portion bonded to the first heat transfer portion on an opposite side to the one end surface, the first heat transfer portion is made of copper or a copper alloy, the second heat transfer portion is made of aluminum or an aluminum alloy, an alumite film is formed on at least a portion of a surface of the second heat transfer portion, and the second heat transfer portion is formed in a plate shape that protrudes from a circumference of the first heat transfer portion.

The nickel base plating layer is formed on the one end surface of the heat transfer member. This nickel base plating layer can be kept in a state where oxidization thereof is suppressed by the gold plating layer. When the heat generating component is soldered to the one end surface of the heat transfer member, the gold plating layer blends into the melted solder and the solder portion is soldered to the nickel base plating layer. The melted solder attaches favorably to the nickel base plating layer plated with gold, and is favorably soldered to the nickel base plating layer of which oxidization is suppressed. As a result, voids are unlikely to occur in the surface of the heat transfer member. Also, the portion of the heat transfer member on the side to which the heat generating component is mounted is the first heat transfer portion that is made of copper or a copper alloy, and thus heat can be favorably conducted from the heat generating component to the heat transfer member. Also, the portion of the heat transfer member on the opposite side to which the heat generating component is mounted is the second heat transfer portion that is made of aluminum or an aluminum alloy, and thus heat conducted by the heat transfer member can be favorably conducted toward the opposite side to side of the substrate on which the heat generating component is mounted. Also, the alumite film is formed on at least a portion of the surface of the second heat transfer portion, and the alumite film has insulating properties. Thus, even if a heat dissipating member such as a heat sink is disposed on the portion of the surface of the second heat transfer portion where the alumite film is formed, insulating properties between the heat transfer member and the heat dissipating member can be easily ensured. Furthermore, the second heat transfer portion protrudes in a plate shape from the circumference of the first heat transfer portion, and thus the thermal resistance of the second heat transfer portion is reduced and the surface area is increased. As a result of suppressing the generation of voids, and decreasing the thermal resistance and the surface area of the second heat transfer portion as described above, heat generated by the heat generating component can be effectively released from the second heat generating portion via the heat dissipating member and the like, and the thermal performance is improved.

The heat transfer member-equipped substrate may further include a thermosetting adhesive that adheres a surface of the second heat transfer portion that protrudes from the circumference of the first heat transfer portion and faces the first heat transfer portion side to the other main surface of the substrate. The heat transfer member is adhered to the substrate by the thermosetting adhesive, and thus the heat transfer member is unlikely to come loose from the substrate during soldering.

The heat transfer member-equipped substrate may further include a heat dissipating member installed on the other main surface side of the substrate, wherein the other end portion of the heat transfer member protrudes from the other main surface of the substrate, the heat dissipating member is provided with a recessed portion in which the other end portion of the heat transfer member is housed, and a heat conductive material is provided between the recessed portion and the other end portion of the heat transfer member. In this case, the heat conductive material is provided between the recessed portion and the other end portion of the heat transfer member, and thus the state in which the heat conductive material is provided between the heat transfer member and the heat dissipating member is stable. Accordingly, the ability to dissipate heat via the heat dissipating member is stable.

Also, the method for manufacturing a heat transfer member-equipped substrate is as follows.

A method for manufacturing a heat transfer member-equipped substrate including, (a) a step of preparing a heat transfer member that includes a first heat transfer portion provided with one end surface and a second heat transfer portion bonded to the first heat transfer portion on an opposite side to the one end surface, the first heat transfer portion being made of copper or a copper alloy, the second heat transfer portion being made of aluminum or an aluminum alloy, a nickel base plating layer being formed on at least the one end surface, a gold plating layer that suppresses oxidization of the nickel base plating layer being formed on a surface of the nickel base plating layer, an alumite film being formed on at least a portion of a surface of the second heat transfer portion, and the second heat transfer portion being formed in a plate shape that protrudes from a circumference of the first heat transfer portion; (b) a step of inserting the heat transfer member into a through hole in a substrate; and (c) a step of soldering a heat generating component to the one end surface of the heat transfer member.

The nickel base plating layer is formed on the one end surface of the heat transfer member. This nickel base plating layer is kept in a state where oxidization thereof is suppressed by the gold plating layer. When the heat generating component is soldered to the one end surface of the heat transfer member, the gold plating layer blends into the melted solder and the solder portion is soldered to the nickel base plating layer. Thus, the solder portion attaches favorably to the gold plating layer, and is favorably soldered to the nickel base plating layer of which oxidization is suppressed. As a result, voids are unlikely to occur in the surface of the heat transfer member. Also, the portion of the heat transfer member on the side to which the heat generating component is mounted is the first heat transfer portion that is made of copper or a copper alloy, and thus heat can be favorably conducted from the heat generating component to the heat transfer member. Also, the portion of the heat transfer member on the opposite side to which the heat generating component is mounted is the second heat transfer portion that is made of aluminum or an aluminum alloy, and thus heat conducted by the heat transfer member can be favorably conducted toward the opposite side to side of the substrate on which the heat generating component is mounted. Also, the alumite film is formed on at least a portion of the surface of the second heat transfer portion, and the alumite film has insulating properties. Thus, even if a heat dissipating member such as a heat sink is disposed on the portion of the surface of the second heat transfer portion where the alumite film is formed, insulating properties between the heat transfer member and the heat dissipating member can be easily ensured. Furthermore, the second heat transfer portion protrudes in a plate shape from the circumference of the first heat transfer portion, and thus the thermal resistance of the second heat transfer portion is reduced and the surface area is increased. Accordingly, heat generated by the heat generating component can be effectively released from the second heat generating portion via the heat dissipating member and the like.

In the step (a), the gold plating layer may be formed to a thickness of 0.01 μm or more to 0.03 μm or less. The gold plating layer can be formed to be thin so as to blend with solder at the time of soldering.

The heat transfer member may include a flange portion that protrudes in a flange shape at an end portion thereof on the opposite side to the one end surface, and after the step (b) and before the step (c), the flange portion may be adhered to the other main surface of the substrate using a thermosetting adhesive. The heat transfer member is adhered to the substrate by the thermosetting adhesive, and thus the heat transfer member is unlikely to come loose from the substrate during soldering.

Specific examples of a heat transfer member-equipped substrate and a manufacturing method of a heat transfer member-equipped substrate of the present disclosure will be described below with reference to the drawings. Note that the present disclosure is not limited to these illustrative examples, but is indicated by the claims, and all changes that come within the meaning and range of equivalency of the claims are intended to be embraced therein.

### Embodiment

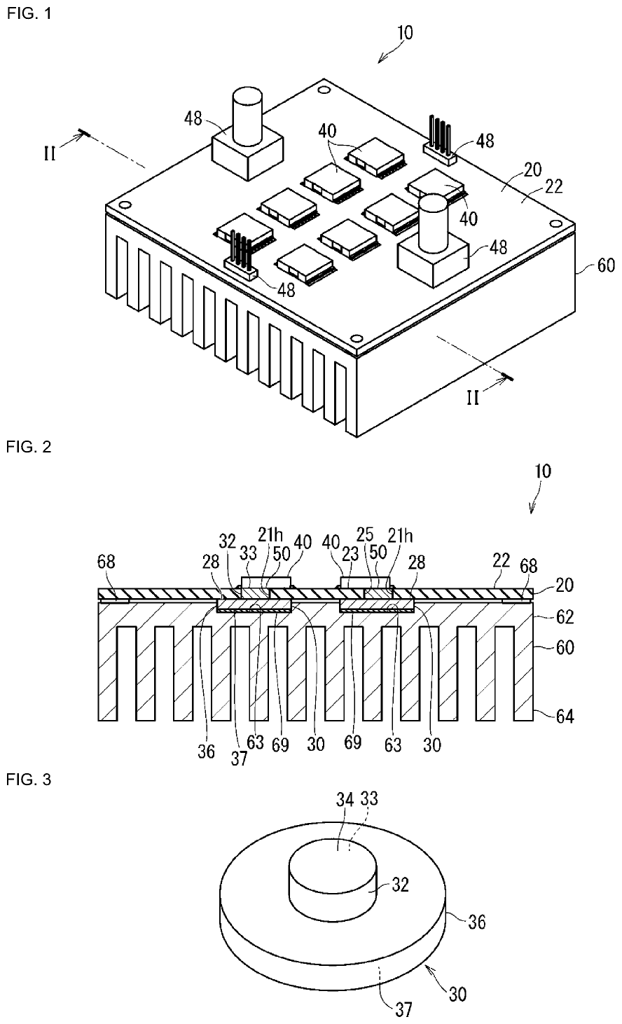

A heat transfer member-equipped substrate and a method for manufacturing a heat transfer member-equipped substrate are described below. FIG. 1 is a perspective view showing a heat transfer member-equipped substrate 10. FIG. 2 is a cross-sectional view taken along line II-II in FIG. 1.

The heat transfer member-equipped substrate 10 is a substrate that is to be installed in an electric junction box, for example. The electric junction box is provided on a power supply path between a power source and various electronic components in an automobile, for example.

The heat transfer member-equipped substrate 10 includes a substrate 20, a heat transfer member 30, a heat generating component 40, and a solder portion 50.

The substrate 20 is plate shaped. The substrate 20 is provided with a through hole 21h that is open at two sides thereof. More specifically, the substrate 20 includes an insulating plate 22 that is made of an insulating material. The through hole 21h is formed in the insulating plate 22. A conductive layer 23 that is made of a metal such as copper foil is formed on one main surface of the insulating plate 22 (the upper surface in FIGS. 1 and 2). The conductive layer 23 is formed in a region where the heat generating component 40 is soldered and a region that forms a predetermined wiring circuit. FIGS. 5, 6, 8, and the like referred to below show the conductive layer 23 in the region to which the heat generating component 40 is to be mounted. A conductive layer 25 is also provided on the inner circumferential surface of the through hole 21h. The conductive layer 25 may be connected to the conductive layer 23 at a peripheral edge portion on one side of the through hole 21h.

A conductive layer may also be provided on the other main surface of the insulating plate 22 (the lower surface in FIG. 2). A conductive layer may also be provided on an intermediate layer located in the thickness direction of the insulating plate 22.

In the present embodiment, the through hole 21h is a circular hole. The through hole 21h does not necessarily need to be a circular hole, and may be a hole with an oval or polygon shape, or the like.

The heat generating component 40 is mounted on a one main surface side of the substrate 20. The heat generating component 40 is a component that generates heat, and is, for example, a semiconductor switching element exemplified by a field effect transistor (also referred to below as an “FET”). The element may be a resistor, a coil, or a capacitor.

The heat generating component 40 includes an element main body and a terminal. The terminal is provided on a surface of the element main body that is on the side mounted to the substrate 20. The portion of the conductive layer 23 formed around the through hole 21h is formed in a shape that corresponds to the terminal. For example, the terminal is provided in a region that expands in a square shape, and the portion of the conductive layer 23 formed around the through hole 21h is also formed in a region that expands in a square shape similar to the terminal. The heat generating component 40 is mounted on the substrate 20 in a state where the entire terminal is soldered to the conductive layer 23.

The heat generating component 40 may include another terminal that protrudes from the element main body. The other terminal may also be soldered to another conductive layer 23 formed on the one main surface of the substrate 20.

The heat transfer member 30 is made of metal. It is preferable that the soldered portion of the heat transfer member 30 is made of copper or a copper alloy. The heat transfer member 30 is installed in the through hole 21h. In other words, the heat transfer member 30 includes a portion that is shaped to match the internal space of the through hole 21h. In a state where the heat transfer member 30 is installed in the through hole 21h, one end surface of the heat transfer member 30 is exposed on the one main surface side of the substrate 20. Here, the one main surface of the substrate 20 and the one end surface of the heat transfer member 30 are flush. The one end surface of the heat transfer member 30 opposes the heat generating component 40 mounted on the one main surface side of the substrate 20, from the substrate side 20. The one end surface of the heat transfer member 30 is surrounded by the conductive layer 23 that is formed so as to surround the through hole 21h in the one main surface of the substrate. The terminal of the heat generating component 40 is soldered to the conductive layer 23 around the through hole 21h and is also soldered to the one end surface of the heat generating component 30.

The solder portion 50 is a portion where the terminal of the heat generating component 40 is soldered to the one end surface of the heat transfer member 30. The main component of the solder is tin, and thus the main component of the solder portion 50 is also tin.

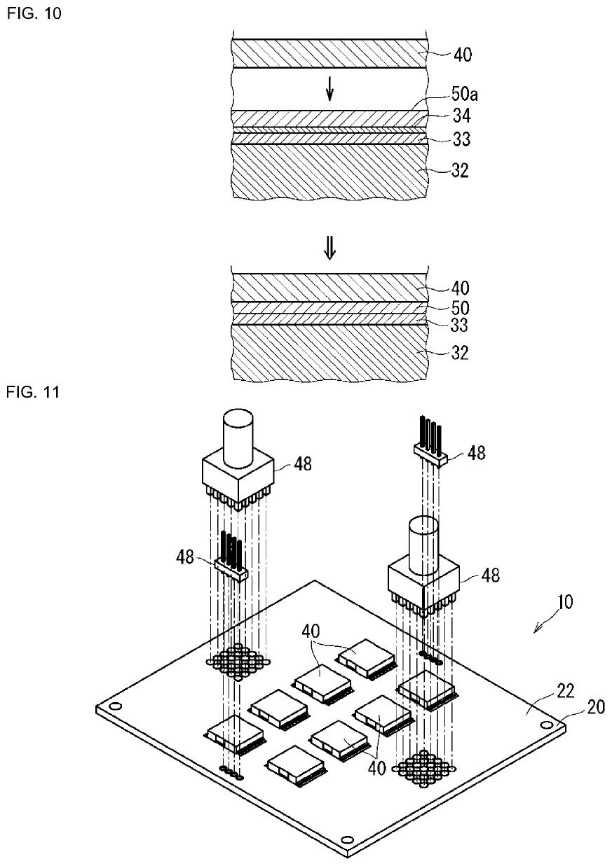

At least the one end face of the heat generating component 30 is provided with a nickel base plating layer 33 (see FIG. 10). The solder portion 50 is bonded to the nickel base plating layer 33, on the heat transfer member 30 side. Also, a gold plating layer 34 (see FIG. 10) for suppressing oxidization of the nickel base plating layer 33 blends into the solder portion 50. The gold plating layer 34 is formed to be thin using a plating method that is performed for a very short period of time. In other words, the gold plating layer 34 is so thin that it melts into the solder at the time of soldering. The gold plating layer 34 may remain between the nickel base plating layer 33 and the solder portion 50.

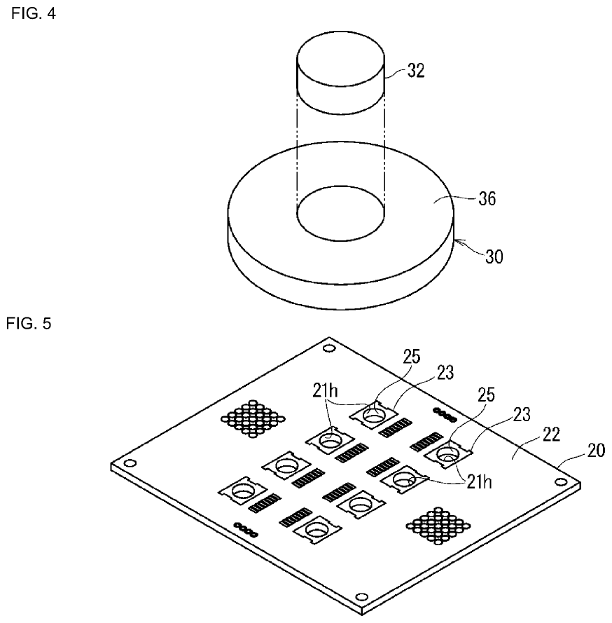

FIG. 3 is a perspective view of the heat transfer member 30 and FIG. 4 is an exploded perspective view of the heat transfer member 30. More specifically, as shown in FIGS. 1 to 4, the heat transfer member 30 includes a first heat transfer portion 32 and a second heat transfer portion 36. The first heat transfer portion 32 is a portion on which the one end surface of the heat transfer member 30 is formed. The second heat transfer portion 36 is a portion that is bonded to the first heat transfer portion 32 from the opposite side to the one end surface.

The first heat transfer portion 32 is shaped to be disposed in the through hole 21h. Here, the first heat transfer portion 32 has a round columnar shape. The height of the first heat transfer portion 32 is the same as the thickness of the substrate 20. The diameter of the first heat transfer portion 32 is made smaller (marginally smaller) than the diameter of the through hole 21h. The first heat transfer portion 32 is disposed in the through hole 21h such that the one end surface thereof is flush with the one main surface of the substrate 20. The first heat transfer portion 32 is made of copper or a copper alloy. Accordingly, the first heat transfer portion 32 is favorably soldered to the heat generating component 40. Also, the first heat transfer portion 32 may be favorably soldered to the conductive layer 25 in the through hole 21h. Also, the first heat transfer portion 32, which is made of copper or a copper alloy, has favorable heat conducting properties. It should be noted that the size of the first heat transfer portion 32 may be set such that the first heat transfer portion 32 can be press fitted into the through hole 21h, or set such that the first heat transfer portion 32 is inserted into the through hole 21h with an interval therebetween.

The second heat transfer portion 36 may be made of aluminum or an aluminum alloy. Also, an alumite film 37 may be formed on at least a portion of the surface of the second heat transfer portion 36. While the heat conducting properties of aluminum or an aluminum alloy are inferior to those of copper or a copper alloy, aluminum or an aluminum alloy is more favorable than other common insulating materials such as resin, for example. Thus, the second heat transfer portion 36 made of aluminum or an aluminum alloy also has favorable heat conducting properties. Also, the alumite film 37 exhibits insulating properties. Thus, at least a portion of the surface of the second heat transfer portion 36 can be provided with insulating properties. It is preferable that the alumite film 37 is formed on at least the other end surface of the second heat transfer portion 36 (the surface facing a heat dissipating member 60). The alumite film 37 may also be formed on the circumferential surface of the second heat transfer portion 36.

The configuration with which the first heat transfer portion 32 and the second heat transfer portion 36 are bonded to each other is not particularly limited. For example, the first heat transfer portion 32 and the second heat transfer portion 36 may be bonded to each other by using a method for bonding different metals such as a diffusion bonding method and a roll bonding method, for example. Also, a clad material in which a flat plate shaped copper plate member and an aluminum plate member have been diffusion bonded may be machined into the shape of the heat transfer portion 30 through grinding.

The other end portion of the heat transfer portion 30 protrudes from the other main surface of the substrate 20. Here, the second heat transfer portion 36 is formed in a plate shape that protrudes from the circumference of the first heat transfer portion 32. The second heat transfer portion 36 protrudes from the other main surface of the substrate 20. The second heat transfer portion 36 has a round plate shape. In a state where the first heat transfer portion 32 is inserted into the through hole 21h, the second heat transfer portion 36 can be abutted against the other main surface of the substrate 20, around the through hole 21h. Accordingly, the heat transfer member 30 is positioned in the thickness direction of the substrate 20. The second heat transfer portion 36 may have an oval plate shape or polygonal plate shape. The second heat transfer portion does not necessarily need to extend around the first heat transfer portion.

The surface of the second heat transfer portion 36 that protrudes from the circumference of the first heat transfer portion 32 and faces the first heat transfer portion 32 side may be adhered to the other main surface of the substrate 20 by a thermosetting adhesive 28. The thermosetting adhesive 28 sets when heated and does not soften even when reheated. Accordingly, if the second heat transfer portion 36 is adhered to the substrate 20 by the thermosetting adhesive 28, the heat transfer member 30 is unlikely to come loose from the substrate 20 even when the heat transfer member 30 and the substrate 20 are heated during soldering.

Note that, in FIGS. 1, 2, and the like, components 48 other than the heat generating component 40 are also mounted on the substrate 20. The components 48 are terminals, connectors, or the like for connecting wires of the substrate 20 to another portion.

Also, here, the heat dissipating member 60 is provided on the other main surface side of the substrate 20. The heat dissipating member 60 is made of a material with favorable heat conducting properties such as copper, a copper alloy, aluminum, and an aluminum alloy. The heat dissipating member 60 incudes a plate portion 62 and a heat dissipation structure portion 64. The plate portion 62 has a flat surface, and is installed so that the flat surface faces the other main surface of the substrate 20. The heat dissipation structure portion 64 is shaped to have a finned structure, for example, in order to increase the surface area. Heat that has reached the heat dissipating member 60 is released to the outside from the heat dissipation structure portion 64.

In a state where the heat dissipating member 60 is provided on the other main surface of the substrate 20, an insulating spacer 68 is interposed between one main surface of the heat dissipating member 60 and the other main surface of the substrate 20. The insulating spacer 68 may be provided spanning the entire one main surface of the heat dissipating member 60, excluding the portion where the heat dissipating member 30 is provided, or partially on the one main surface. Here, the insulating spacer 68 is provided at four corner portions of the one main surface of the heat dissipating member 60.

The one main surface of the heat dissipating member 60 is provided with a recessed portion 63 that houses the other end portion of the heat transfer member 30, here the second heat transfer portion 36. Here, the recessed portion 63 has a bottomed round hole shape. The diameter of the recessed portion 63 is the same as or larger (slightly larger) than the diameter of the second heat transfer portion 36. Also, in a state where the one main surface of the heat dissipating member 60 and the other main surface the substrate 20 face each other via the insulating spacer 68, the bottom surface of the recessed portion 63 is provided at a position spaced apart from the other end surface of the heat transfer member 30. More specifically, the second heat transfer portion 36 protrudes from the other main surface of the substrate 20, and is partially stored in the recessed portion 63. A heat conductive material 69 is provided on the bottom side in the recessed portion 63. The heat conductive material 69 is a material that is also called a thermal interface material (TIM). Specifically, the heat conductive material 69 is, for example, a heat conductive sheet that uses a silicon resin, heat conductive grease, or the like. The heat conductive material 69 is interposed, in the recessed portion 63, between the other end surface of the heat transfer member 30 (the outward facing end surface of the second heat transfer portion 36) and the bottom surface of the recessed portion 63. Heat that has reached the second heat transfer portion 36 can be transferred to the heat dissipating member 60 via the heat conductive material 69.

An example of the method for manufacturing the above heat transfer member-equipped substrate 10 will be described.

First, the heat transfer member 30 is prepared (step (a), see FIGS. 3 and 4). As described above, prior to soldering, the nickel base plating layer 33 is formed on at least the one end surface of the heat transfer member 30. Also, the gold plating layer 34 is formed on the surface of the nickel base plating layer 33.

More specifically, the first heat transfer portion 32 of the heat transfer member 30 is made of pure copper (alloy number C1020) or the like. The size of the first heat transfer portion 32 is made to match the size of the heat generating component 40 mounted on the substrate 20. For example, assume that the heat generating component 40 is a MOSFET (Metal Oxide Semiconductor Field Effect Transistor) that corresponds to a package TO-263, which is a standardized article according to JEDEC (Joint Electron Device Engineering Council) standards. In this case, the size of the drain electrode of the heat generating component 40 is approximately 6 mm long and 6 mm wide, and thus it is sufficient that the outer diameter of the first heat transfer portion 32 be set to 6 mm.

Note that the larger the outer diameter of the heat transfer member is, the smaller the thermal resistance is and the more likely heat is to be conducted. However, if the size of the heat transfer member 30 is matched to the size of the heat generating component 40, it becomes difficult to increase the size of the first heat transfer portion 32 of and the thermal resistance thereof increases.

The axial length of the first heat transfer portion 32 may be the same as the thickness of the substrate 20 so that the one end surface of the heat transfer member 30 soldered to the substrate 20 is arranged on the same plane as the conductive layer (also referred to as a “land”) 23 of the substrate 20. For example, if the thickness of the substrate 20 is 2 mm, the axial length of the first heat transfer portion 32 is 2 mm.

Surface processing is performed on the first heat transfer portion 32 while the surface of the second heat transfer portion 36 is masked. Here, the portion of the surface of the first heat transfer portion 32 excluding the portion bonded to the second heat transfer portion 36, that is, the entirety of the one end surface and the circumferential surface of the first heat transfer portion 32, undergoes surface processing. The surface processing performed on the first heat transfer portion 32 is electroless nickel base flash gold plating processing. The thickness of the nickel base plating layer 33 is, for example, 1 μm or more to 3 μm or less, and the thickness of the gold plating layer 34 is, for example, 0.01 μm or more to 0.03 μm or less, the nickel base plating layer and the gold plating layer being formed through the electroless nickel base gold plating processing.

The second heat transfer portion 36 is made of aluminum (alloy number A1050). The outer diameter of the second heat transfer portion 36 is preferably set to a diameter with which interference with the heat dissipating member 60 or the like does not occur in a state where the heat transfer member 30 is soldered to the substrate 20. For example, the outer diameter of the second heat transfer portion 36 is set to 20 mm. The thickness of second heat transfer portion 36 may be set as large as possible so as to increase the thermal capacity thereof. Naturally, if the thermal capacity of the second heat transfer portion 36 is excessively large, the reflow setting temperature at the time of soldering needs to be set high, in which case the reflow setting temperature may exceed the thermal resistance temperature of other mounted components. It is preferable that the thickness of the second heat transfer portion 36 is set in consideration of the above, and may be set to 20 mm, for example.

The surface of the second heat transfer portion 36 is anodized through anodization. Accordingly, the alumite film 37 is formed on the other end surface and the circumferential surface of the second heat transfer portion 36. The thickness of the alumite film 37 is, for example, 20 μm or more to 70 μm or less.

A substrate 20 such as that shown in FIG. 5 is prepared separate to the heat transfer member 30. The through hole 21h is formed in the substrate 20. The conductive layers 23 and 25 are formed on the substrate 20. The outer diameter of the through hole 21h is set such that first heat transfer portion 32 of the heat transfer member 30 can be installed thereto. Similar to the surface of the first heat transfer portion 32, the surface of the conductive layers 23 and 25 may be subjected to electroless nickel base flash gold plating processing. The thickness of the nickel base plating layer in this case may be set to 1 μm or more to 3 μm or less. The thickness of the gold plating layer may be set to 0.01 μm or more to 0.03 μm or less. The conductive layer 23 forms a power supply circuit and a signal circuit on the substrate 20. The substrate 20 is provided with through holes to which components 48 such as a power supply terminal and a signal terminal for connecting a power supply circuit and a signal circuit to an external circuit are to be attached.

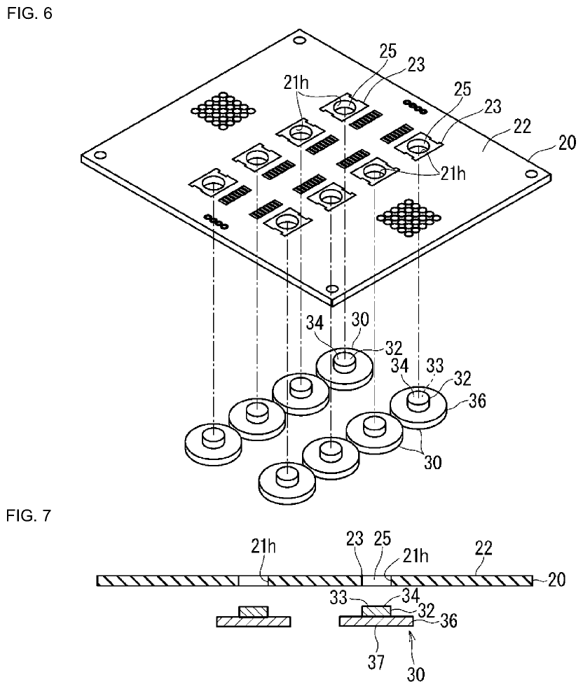

Next, as shown in FIGS. 6 and 7, the heat transfer member 30 is inserted into the through hole 21h in the substrate 20 (step (b)). The heat transfer member 30 is inserted from the other main surface side of the substrate 20. Here, eight through holes 21h are provided, and a heat transfer member 30 is inserted into each of the through holes 21h.

In order to keep the heat transfer member 30 from coming loose during soldering, it is preferable that the second heat transfer portion 36 and the substrate 20 are adhered to each other by the thermosetting adhesive 28. A thermosetting epoxy adhesive is used as the thermosetting adhesive 28, for example. The application region of the thermosetting adhesive 28 is the contract region between the substrate 20 and the second heat transfer portion 36, that is, the portion between the surrounding portion of the through hole 21h in the other main surface of the substrate 20 and the surface of the second heat transfer portion 36 that comes into contact with the substrate 20. The thermosetting adhesive 28 is preferably applied so as not to flow between the first heat transfer portion 32 and the through hole 21h.

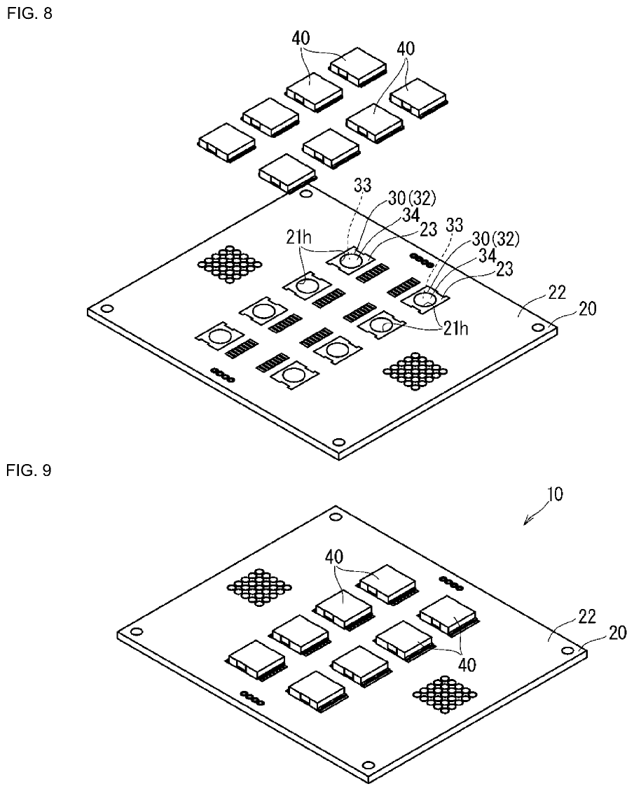

As shown in FIGS. 8 and 9, heat generating components 40 are respectively soldered to the one end surfaces of the heat transfer members 30 (step (C)). More specifically, on the one main surface of the substrate 20, the one end surface of the heat generating component 40 is exposed and spreads integrated with a portion of the conductive layer 23 (land) in the surrounding region thereof, and the terminal of the heat generating component 40 (here, a drain terminal of a MOSFET) is soldered to surfaces thereof. The other terminal of the heat generating component 40 (here, the source terminal or gate terminal of the MOSFET) is soldered to another portion (land) of the conductive layer 23 on the one main surface of the substrate 20. The soldering is performed using reflow soldering, for example.

Here, as shown in FIG. 10, nickel base gold flash plating processing is performed on the surface of the first heat transfer portion 32. That is, the nickel base plating layer 33 is formed on the surface of the first heat transfer portion 32. The gold plating layer 34 is formed on the surface of the nickel base plating layer 33. A solder paste 50a is applied to the surface of the gold plating layer 34, and is heated with the heat generating component 40 placed thereon. Thus, once the terminal of the heat generating component 40 has been soldered to the first heat transfer portion 32, the solder is soldered to the nickel base plating layer 33 in a state where the gold plating layer 34, which is the outermost layer, is melted into the solder. Accordingly, the melted solder can favorably attach to the surface of the first heat transfer portion 32, and metal oxides considered as generating factors of voids are unlikely to occur, and thus voids are unlikely to occur between the first heat transfer portion 32 and the heat generating component 40. If nickel base gold flash plating is performed on the surfaces of the conductive layers 23 and 25 as well, voids are similarly unlikely to occur. Voids, which are air layers, being unlikely to occur in the solder portion 50 between the heat transfer member 30 and the heat generating component 40 means an increase and variability in the thermal resistance between the heat transfer member 30 and the heat generating component 40 are suppressed.

Also, the wettability of the solder on the surface of the heat transfer member 30 is increased, and thus the melted solder is also more likely to flow into a gap between the first heat transfer portion 32 and the through hole 21h, and the first heat transfer portion 32 and the through hole 21h can be firmly bonded to each other. Accordingly, the connection reliability between the heat transfer member 30 and the substrate 20 is improved. For example, the formation of cracks in a cooling/heating cycle test is reduced.

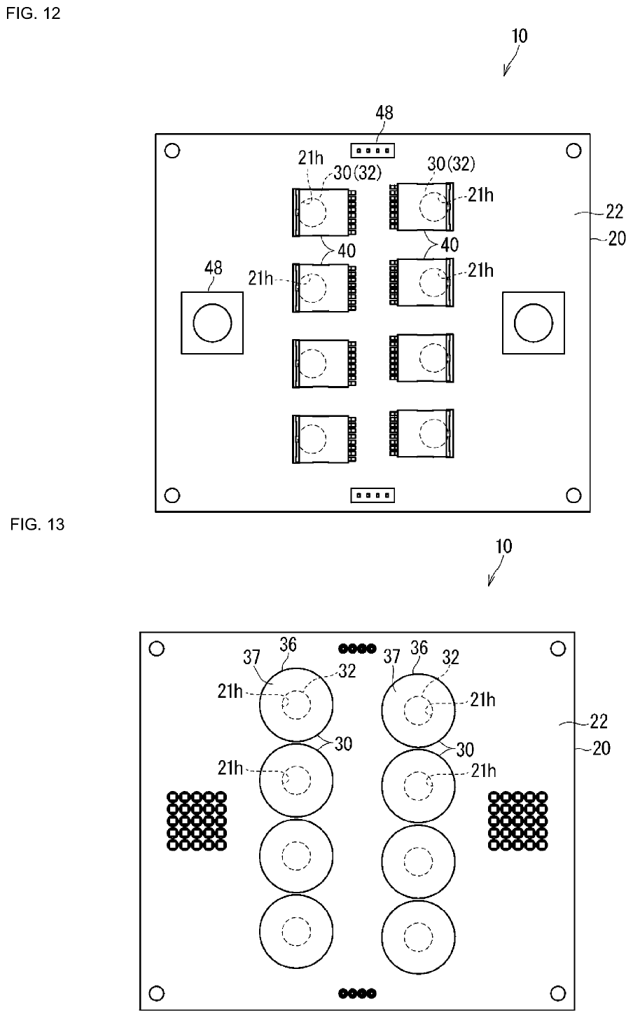

Then, as shown in FIGS. 11, 12, and 13, components 48 such as a power supply terminal and a signal terminal are soldered to the substrate 20.

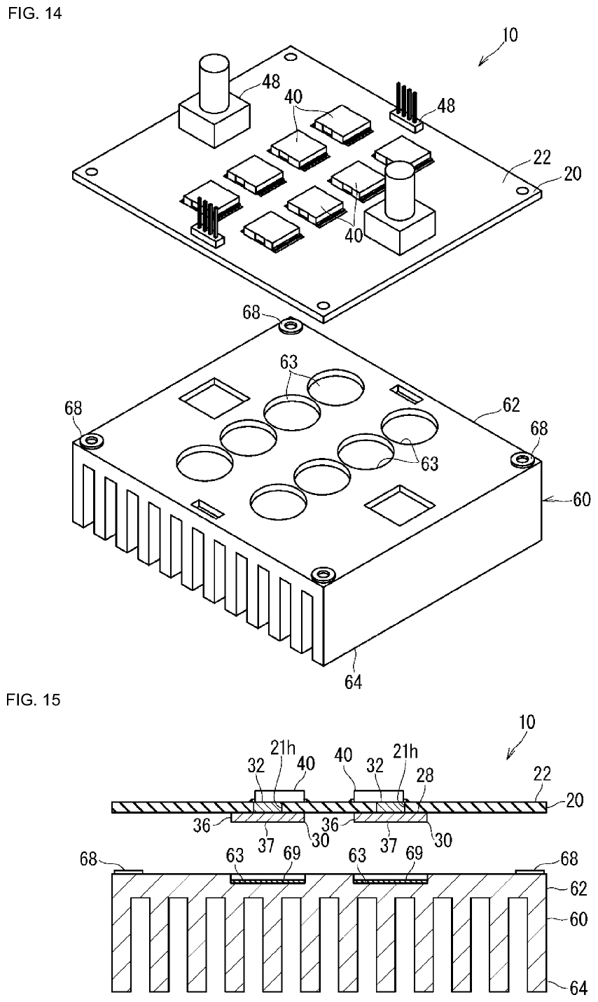

Next, as shown in FIGS. 14 and 15, the heat dissipating member 60 is attached to the other main surface side of the substrate 20. The heat dissipating member 60 and the substrate 20 may be fixed to each other by using a screw or an adhesive.

The recessed portion 63 is formed in the heat dissipating member 60. The heat conductive material 69 is disposed in the recessed portion 63. Here, as the heat conductive material 69, a heat conductive silicon grease with a thermal conductivity of 2 W/m·K or more, and a viscosity of 50 Pa·s to 500 Pa·s is used, for example. The heat conductive silicone grease is applied so as to cover the entire surface of the bottom portion of the recessed portion 63. Then, the other main surface of the second heat transfer portion 36 is pressed into the recessed portion 63, and the thickness of the heat conductive material 69 is controlled to be 0.5 mm to 1.0 mm. The heat conductive material 69 is contained within the recessed portion 63, and thus the interposing state of the heat conductive material 69 between the second heat transfer portion 36 and the heat dissipating member 60 is stable. In particular, if the heat conductive material 69 is a liquid, the liquid is stably contained within the recessed portion 63, and thus the heat conductive material 69 is unlikely to spread out over a large area.

In this heat transfer member-equipped substrate 10, heat generated by the heat-generating component 40 moves to the heat dissipating member 60 via the first heat transfer portion 32, the second heat transfer portion 36, and then the heat conductive material 69. Heat is mainly released to the outside from the heat dissipating member 60.

Here, thermal resistance is expressed with the following formula.

Thermal resistance (° C./W)=thickness (m)÷{cross-section area (m²)×thermal conductivity (W/mK)}

Thus, it can be understood that the larger the cross-section area (the contact area), the smaller the thermal resistance, and the greater the thermal conductivity, the smaller the thermal resistance.

Assuming the material of the first heat transfer portion 32 of the heat transfer member 30 is copper (alloy number C1020), the thermal conductivity is 398 W/mK. Assuming the material of the second heat transfer portion 36 is aluminum (alloy number A1050), the thermal conductivity is 236 W/mK. However, the thermal conductivity of the alumite film 37 of the second heat transfer portion 36 falls to 80 W/mK, which is approximately ⅓ of that prior to processing. If, for example, the material of the second heat transfer portion 36 is copper, the surface thereof needs to be coated with a resin using an insulating process such as electrodeposition coating. In which case, the thermal conductivity largely decreases to 0.4 W/mK. Thus, it is understood that by selecting aluminum or an aluminum alloy as the material of the second heat transfer portion 36 and insulating the second heat transfer portion 36 by using the alumite film 37, insulating properties can be insured and the thermal conductivity can be increased. It is understood from the above formula that, if the thermal conductivity is high, the thermal resistance can be suppressed to a low value.

Furthermore, by making the outer diameter of the second heat transfer portion 36 larger than the outer diameter of the first heat transfer portion 32, for example, by setting the outer diameter of the first heat transfer portion 32 to 6 mm and setting the outer diameter of the second heat transfer portion 36 to 20 mm, the area of contact between the heat transfer member 30 and the heat dissipating member 60 via the heat conductive material 69 (the cross-section area of a portion that conducts heat) can also be increased. In this way, it is understood from the above formula that the thermal resistance can also be reduced by increasing the contact area (cross-section area) between the heat transfer member 30 and the heat dissipating member 60.

With the heat transfer member-equipped substrate 10 and the manufacturing method of the heat transfer member-equipped substrate 10 described above, the nickel base plating layer 33 is formed on the one end surface of the heat transfer member 30. This nickel base plating layer 33 can be kept in a state where oxidation thereof is suppressed by the gold plating layer 34. When the heat generating component 40 is soldered to the one end surface of the heat transfer member 30, the gold plating layer 34 blends into the melted solder, and the solder portion 50 is soldered to the nickel base plating layer 33. The melted solder attaches favorably to the nickel base plating layer 33 plated with gold, and is favorably soldered to the nickel base plating layer 33 of which oxidization is suppressed. As a result, voids are unlikely to occur in the surface of the heat transfer member 30. Accordingly, an increase and variability in thermal resistance are suppressed.

Note that, if the gold plating layer 34 is not provided, an oxide film will form on the surface of a heat transfer member made of copper or the like. Thus, the solder wettability of the surface of the heat transfer member is impaired. If the solder wettability is impaired, voids are more likely to occur in the surface of the heat transfer member.

Also, when the nickel base plating layer 33 and the gold plating layer 34 are formed on the circumferential surface of the heat transfer member 30, melted solder is more likely to flow into a gap between the heat transfer member 30 and the through hole 21h, and the heat transfer member 30 and the substrate 20 are more firmly bonded to each other.

Also, the portion of the heat transfer member 30 on the side to which the heat generating component 40 is mounted is the first heat transfer portion 32 that is made of copper or a copper alloy, and thus heat can be favorably conducted from the heat generating component 40 to the heat transfer member 30. Also, the portion of the heat transfer member 30 on the opposite side to which the heat generating component 40 is mounted is the second heat transfer portion 36 that is made of aluminum or an aluminum alloy, and thus heat conducted by the heat transfer member 30 can be favorably conducted toward the main surface on the opposite side. The alumite film 37 is formed on at least a portion of the surface of the second heat transfer portion 36, and the alumite film 37 has insulating properties. Thus, even if the heat dissipating member 60, which is a heat sink or the like, is disposed on the portion of the surface of the second heat transfer portion 36 where the alumite film 37 is formed, insulating properties between the heat transfer member 30 and the heat dissipating member 60 can be easily ensured. Accordingly, the insulating properties can be ensured between the heat transfer member 30 and the heat dissipating member 60, and heat can be more easily conducted from the heat transfer member 30 to the heat dissipating member 60.

Also, irrespective of the insulating properties of the heat conductive material 69 and the presence or absence of pinholes generated in the heat conductive material 69, the insulating properties between the heat transfer member 30 and the heat dissipating member 60 are ensured by the alumite film 37.

Also, the second heat transfer portion 36 is formed in a plate shape that protrudes from the circumference of the first heat transfer portion 32. Accordingly, the surface area of the other main surface of the second heat transfer portion 36 is increased. Thus, the contact area between the heat transfer member 30 and the heat dissipating member 60 is increased, and heat from the heat transfer member 30 is effectively released via the heat dissipating member 60 and the like.

The heat transfer member 30 and the substrate 20 are adhered to each other by the thermosetting adhesive 28, and thus the heat transfer member 30 is unlikely to come loose from the substrate when soldering is performed.

Also, the heat dissipating member 60 is provided with the recessed portion 63, and the heat conductive material 69 is interposed between the bottom portion of the recessed portion 63 and the other end portion of the heat transfer member 30. Thus, the interposing state of the heat conductive material 69 between the heat transfer member 30 and the heat dissipating member 60 is stabilized. Accordingly, the ability to dissipate heat via the heat dissipating member 60 is stable.

In particular, in the case where the heat conductive material 69 is a liquid such as a heat conductive grease, there is concern that the interval between the heat transfer member 30 and the heat dissipating member 60 will change due to thermal expansion, thermal contraction, and the like of the heat transfer member 30 and the substrate 20. When this interval changes, the manner in which the heat conductive grease spreads may vary. When a liquid such as a thermal conductive grease is filled into the recessed portion 63, the liquid is likely to be kept contained in the recessed portion 63 even if the thermal conductive member 30 and the substrate 20 undergo thermal expansion and thermal contraction. Therefore, the conductivity of heat from the heat transfer member 30 to the heat dissipating member 60 is stable.

### Experimental Examples

The heat generating component 40 was soldered in a working example in which electroless nickel base flash gold plating processing was performed on the surface of the first heat transfer portion 32 of the heat transfer member 30 and in an example regarding a heat transfer member 130 in which electroless nickel base flash gold plating processing was not performed on a surface.

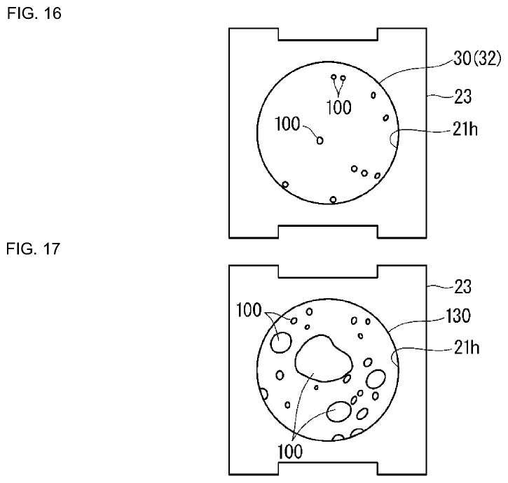

In the former example, as shown in FIG. 16, hardly an voids 100 occurred, and the voids that did occur were small.

In the latter example, as shown in FIG. 17, many voids 100 occurred, including large voids.

Thus, it was found that the generation of voids 100 can be effectively suppressed in the case where the electroless nickel base flash gold plating processing is performed.

Note that, the configurations described in the above embodiment and variations can be appropriately combined provided that no mutual contradictions arise.

1. A heat transfer member-equipped substrate comprising:
a substrate provided with a through hole;
a heat transfer member installed in the through hole;
a heat generating component mounted on one main surface side of the substrate; and
a solder portion where the heat generating component is soldered to one end surface of the heat transfer member,
wherein a nickel base plating layer is formed on at least the one end surface of the heat transfer member,
the solder portion is bonded to the nickel base plating layer in a state where a gold plating layer that suppresses oxidization of the nickel base plating layer is blended into the solder portion,
the heat transfer member includes a first heat transfer portion provided with the one end surface, and a second heat transfer portion directly in contact with and bonded to a surface of the first heat transfer portion on an opposite side to the one end surface,
the first heat transfer portion is made of copper or a copper alloy,
the second heat transfer portion is made of aluminum or an aluminum alloy,
an alumite film is formed on at least a portion of a surface of the second heat transfer portion, and
the second heat transfer portion is formed in a plate shape that protrudes from a circumference of the first heat transfer portion, and extends out on the other main surface of the substrate from the through hole.

2. The heat transfer member-equipped substrate according to claim 1, further comprising:
a thermosetting adhesive that adheres a surface of the second heat transfer portion that protrudes from the circumference of the first heat transfer portion and faces the first heat transfer portion side to the other main surface of the substrate.

3. The heat transfer member-equipped substrate according to claim 1, further comprising:
a heat dissipating member installed on the other main surface side of the substrate,
wherein the other end portion of the heat transfer member protrudes from the other main surface of the substrate,
the heat dissipating member is provided with a recessed portion in which the other end portion of the heat transfer member is housed, and
a heat conductive material is provided between the recessed portion and the other end portion of the heat transfer member.

4. A method for manufacturing a heat transfer member-equipped substrate, comprising:
(a) a step of preparing a heat transfer member that includes a first heat transfer portion provided with one end surface and a second heat transfer portion directly in contact with and bonded to a surface of the first heat transfer portion on an opposite side to the one end surface, the first heat transfer portion being made of copper or a copper alloy, the second heat transfer portion being made of aluminum or an aluminum alloy, a nickel base plating layer being formed on at least the one end surface, a gold plating layer that suppresses oxidization of the nickel base plating layer being formed on a surface of the nickel base plating layer, an alumite film being formed on at least a portion of a surface of the second heat transfer portion, and the second heat transfer portion being formed in a plate shape that protrudes from a circumference of the first heat transfer portion;
(b) a step of inserting the heat transfer member into a through hole in a substrate; and
(c) a step of soldering a heat generating component to the one end surface of the heat transfer member,
wherein, in the step (b), the second heat transfer portion is formed in a state of extending out on the other main surface of the substrate from the through hole.

5. The method for manufacturing a heat transfer member-equipped substrate according to claim 4,
wherein, in the step (a), the gold plating layer is formed to a thickness of 0.01 μm or more to 0.03 μm or less.

6. The method for manufacturing a heat transfer member-equipped substrate according to claim 4, wherein the heat transfer member includes a flange portion that protrudes in a flange shape at an end portion thereof on the opposite side to the one end surface, and
after the step (b) and before the step (c), the flange portion is adhered to the other main surface of the substrate using a thermosetting adhesive.

7. The heat transfer member-equipped substrate according to claim 2, further comprising:
a heat dissipating member installed on the other main surface side of the substrate,
wherein the other end portion of the heat transfer member protrudes from the other main surface of the substrate,
the heat dissipating member is provided with a recessed portion in which the other end portion of the heat transfer member is housed, and
a heat conductive material is provided between the recessed portion and the other end portion of the heat transfer member.

8. The method for manufacturing a heat transfer member-equipped substrate according to claim 5, wherein the heat transfer member includes a flange portion that protrudes in a flange shape at an end portion thereof on the opposite side to the one end surface, and
after the step (b) and before the step (c), the flange portion is adhered to the other main surface of the substrate using a thermosetting adhesive.
